(19) United States
(12) Patent Application Publication
(10) Pub. No.: US 2026/0136542 A1
(43) Pub. Date: May 14, 2026

(54) SEMICONDUCTOR DEVICE AND METHOD FOR FABRICATING THE SAME

(71) Applicant: SK hynix Inc., Gyeonggi-do (KR)

(72) Inventors: Gwang Il JO, Gyeonggi-do (KR); Jong Seo PARK, Gyeonggi-do (KR)

(21) Appl. No.: 19/183,942

(22) Filed: Apr. 21, 2025

(30) Foreign Application Priority Data
Nov. 13, 2024 (KR) 10-2024-0160881

(51) Int. Cl. H10B 12/00

(52) U.S. Cl. CPC H10B 12/485; H10B 12/0335; H10B 12/315; H10B 12/34; H10B 12/482

(57) ABSTRACT

Disclosed are a semiconductor device capable of alleviating or minimizing the interference between the storage node contacts, and a method for fabricating the semiconductor device. A semiconductor device includes a semiconductor substrate; a plurality of bit line structures disposed over the semiconductor substrate; island-shaped storage node contacts that are spaced apart from each other between neighboring bit line structures of the plurality of bit line structures; a plurality of plug isolation layers disposed between the island-shaped storage node contacts; and contact spacers disposed between each of the storage node contacts and each of the plurality of plug isolation layers, each contact spacer having different thicknesses at a central portion of the contact spacer and at both ends.

### CROSS-REFERENCE TO RELATED APPLICATIONS

The present application claims priority under 35 U.S.C 119(a) to Korean Patent Application No. 10-2024-0160881, filed on Nov. 13, 2024, which is incorporated herein by reference in its entirety.

### BACKGROUND

### 1. Field

Embodiments of the present disclosure relate to a semiconductor device and a method for fabricating the same, and more particularly, to a semiconductor device including a storage node contact, and a method for fabricating the semiconductor device.

### 2. Description of the Related Art

As the integration degree of semiconductor devices increases and their sizes decrease, the size of contact plugs decreases. As the contact plugs become smaller, the aspect ratio of the contact holes increases.

However, during an etching process for forming high-aspect-ratio contact holes, misalignment, contact hole not open, etc. may occur.

In this way, the electrical characteristics of semiconductor devices may deteriorate due to the defects of high-aspect-ratio contact holes, and the process for forming contact plugs becomes difficult. Therefore, it is required to develop a method for improving the difficulty.

### SUMMARY

Embodiments of the present disclosure are directed to a semiconductor device capable of alleviating or minimizing the interference between the storage node contacts, and a method for fabricating the semiconductor device.

In accordance with an embodiment of the present disclosure, a semiconductor device includes a semiconductor substrate; a plurality of bit line structures disposed over the semiconductor substrate; island-shaped storage node contacts that are spaced apart from each other between neighboring bit line structures of the plurality of bit line structures; a plurality of plug isolation layers disposed between the island-shaped storage node contacts; and contact spacers disposed between each of the storage node contacts and each of the plurality of plug isolation layer, each contact space having different thicknesses at a central portion and at both ends.

In accordance with another embodiment of the present disclosure, a method for fabricating a semiconductor device includes forming a plurality of bit line structures over a semiconductor substrate; forming island-shaped storage node contacts that are spaced apart from each other between neighboring bit line structures of the plurality of bit line structures; replacing a surface of each storage node contact with a contact spacer; and forming plug isolation layers to gap-fill a space between neighboring storage node contacts of the island-shaped storage node contacts.

### BRIEF DESCRIPTION OF THE DRAWINGS

FIG. 1A is a plan view illustrating a semiconductor device in accordance with an embodiment of the present disclosure.

FIGS. 1B and 1C are cross-sectional views illustrating the semiconductor device in accordance with the embodiment of the present disclosure.

FIG. 2A to FIG. 10C illustrate a method for fabricating a semiconductor device in accordance with an embodiment of the present disclosure.

### DETAILED DESCRIPTION

Embodiments of the present disclosure will be described below in more detail with reference to the accompanying drawings. The present invention may, however, be embodied in different forms and should not be construed as limited to the embodiments set forth herein. Rather, these embodiments are provided so that this disclosure will be thorough and complete, and will fully convey the scope of the present disclosure to those skilled in the art. Throughout this disclosure, like reference numerals refer to like parts throughout the various figures and embodiments of the present disclosure.

Hereinafter, the various embodiments of the present disclosure will be described in detail with reference to the attached drawings.

The drawings are not necessarily to scale and in some instances, proportions may have been exaggerated in order to clearly illustrate features of the embodiments. When a first layer is referred to as being ‘on’ a second layer or ‘on’ a substrate, it not only refers to a case where the first layer is formed directly on the second layer or the substrate but also a case where a third layer exists between the first layer and the second layer or the substrate.

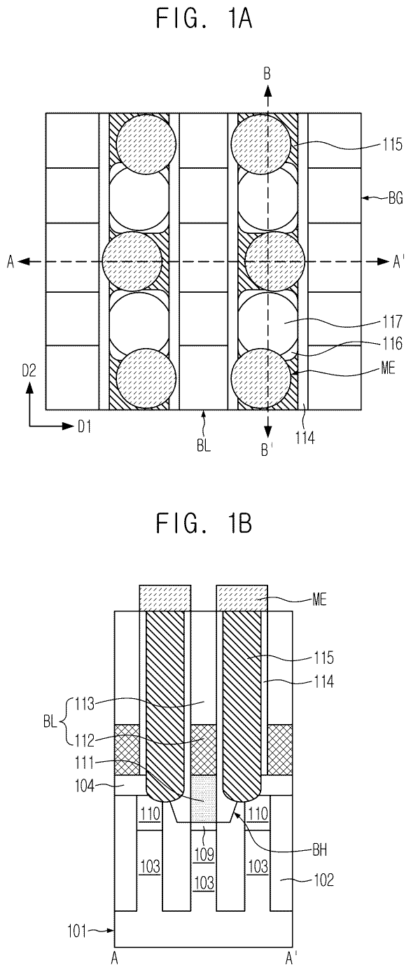

FIG. 1A is a plan view illustrating a semiconductor device in accordance with an embodiment of the present disclosure. FIGS. 1B and 1C are cross-sectional views illustrating the semiconductor device in accordance with the embodiment of the present disclosure. FIG. 1B is a cross-sectional view taken along a line A-A′ shown in FIG. 1A, and FIG. 1C is a cross-sectional view taken along a line B-B′ shown in FIG. 1A.

Referring to FIGS. 1A to 1C, the semiconductor device may include a plurality of memory cells. Each memory cell may include a cell transistor including a buried gate structure BG, a bit line structure BL, and a memory element ME.

An isolation layer 102 and an active region 103 may be formed in a substrate 101. A plurality of active regions 103 may be defined by the isolation layer 102. Each active region 103 may have a bar shape having a long axis and a short axis. The active regions 103 may be disposed to be spaced apart from each other by a predetermined distance.

The substrate 101 may be formed of a material containing silicon. The substrate 101 may include silicon, monocrystalline silicon, polysilicon, amorphous silicon, silicon germanium, monocrystalline silicon germanium, polycrystalline silicon germanium, carbon-doped silicon, a combination thereof, or a multi-layer thereof. The substrate 101 may also include other semiconductor materials, such as germanium (Ge). The substrate 101 may also include a III/V-group semiconductor substrate, for example, a compound semiconductor substrate, such as gallium arsenide (GaAs). The substrate 101 may also include a SOI (Silicon-On-Insulator) substrate. The isolation layer 102 may be formed by a Shallow Trench Isolation (STI) process.

A line-shaped buried gate structure BG extending in a first direction D1 may be formed in the substrate 101. The buried gate structure BG may include a gate dielectric layer 106 formed on the surface of the gate trench 105, and a gate electrode 107 and a gate capping layer 108 that are formed over the gate dielectric layer 106 to fill the gate trench 105.

To be specific, the line-shaped gate trench 105 may be formed across the active region 103 and the isolation layer 102 in the first direction D1 over the substrate 101. The gate trench 105 may be formed to have a predetermined depth in an area defined by a hard mask layer 104 that is formed on the surface of the substrate 101. The bottom surface of the gate trench 105 may be disposed at a higher level than the bottom surface of the isolation layer 102. The gate trench 105 may have a shallower depth than the isolation layer 102. According to another embodiment of the present disclosure, the bottom portion of the gate trench 105 may have a curvature. According to another embodiment of the present disclosure, the isolation layer 102 in a direction that the gate trench 105 extends may be etched to have a predetermined depth to form a fin in the active region 103.

A gate dielectric layer 106 may be formed on the surface of the gate trench 105. A gate electrode 107 partially filling the gate trench 105 may be formed over the gate dielectric layer 106. A gate capping layer (which is a sealing layer) 108 may be formed over the gate electrode 107 to fill the remaining portion of the gate trench 105. The upper surface of the gate capping layer 108 may be disposed at the same level as the upper surface of the hard mask layer 104. The upper surface of the gate electrode 107 may be disposed at a lower level than the upper surface of the substrate 101. The gate electrode 107 may include a low-resistance metal material. The gate electrode 107 may include a combination or a stacked structure of at least one among a metal material, a metal nitride, and polysilicon. For example, the gate electrode 107 may be formed by sequentially stacking titanium nitride and tungsten. According to another embodiment of the present disclosure, the gate electrode 107 may be formed of titanium nitride only (TiN Only). According to another embodiment of the present disclosure, the gate electrode 107 may include a stacked structure of a metal material and polysilicon.

First and second impurity regions 109 and 110 may be formed in the substrate 101. The first and second impurity regions 109 and 110 may be referred to as ‘junction regions’or ‘source/drain regions’. The first and second impurity regions 109 and 110 may be spaced apart from each other by the gate trench 105. As a result, the gate electrode 107 and the first and second impurity regions 109 and 110 may become a cell transistor. The cell transistor may improve the short channel effect due to the gate electrode 107 having a buried gate structure.

A bit line contact 111 may be formed over the substrate 101. The bit line contact 111 may be coupled to the first impurity region 109. The bit line contact 111 may be disposed in a bit line contact hole BH. The bit line contact hole BH may expose the first impurity region 109. The lower surface of the bit line contact 111 may be lower than the upper surface of the substrate 101. The bit line contact 111 may be formed of polysilicon or a metal material. A portion of the bit line contact 111 may have a line width which is thinner than the diameter of the bit line contact hole BH. Accordingly, a gap may be formed on each side of the bit line contact 111. The gap may be formed independently on each side of the bit line contact 111. As a result, one bit line contact 111 and a pair of gaps may be disposed in the bit line contact hole BH, and the pair of gaps may be isolated by the bit line contact 111.

A bit line structure BL may be formed over the bit line contact 111. The bit line contact 111 may couple the bit line structure BL and the active region to each other. The bit line structure BL may include a bit line 112 and a bit line hard mask 113 over the bit line 112. Referring to FIG. 1, the bit line structure BL may have a line shape extending in a direction crossing the buried gate structure BG, i.e., in a second direction D2. A portion of the bit line 112 may be coupled to the bit line contact 111.

The line widths of the bit line 112 and the bit line contact 111 may be the same. The bit line 112 may extend in the second direction D2 while covering the upper surface of the bit line contact 111. The bit line 112 may include a metal material. The bit line hard mask 113 may include a dielectric material.

A bit line spacer 114 may be formed on the sidewalls of the bit line contact 111 and the bit line structure BL. The bit line spacer 114 may extend in the second direction D2 along the profile of the bit line structure BL. The bit line spacer 114 may extend from the sidewall of the bit line structure BL to the bit line contact 111. The bit line spacer 114 may fill the gap between the bit line contact 111 and the bit line contact hole BH.

The bit line spacer 114 may include a single-layer or multi-layer structure. The bit line spacer 114 may include a dielectric material. The bit line spacer 114 may include at least one among silicon oxide, silicon nitride, and a low-k material, or a combination of one or more of them.

Storage node contacts 115 may be formed between the neighboring bit line structures BL. Each of the storage node contacts 115 may be coupled to the second impurity region 110.

The storage node contacts 115 may be an island shape spaced apart in the first and second directions D1 and D2. The storage node contacts 115 may be spaced apart in the first direction D1 by the bit line structure BL. The storage node contacts 115 may be spaced apart in the second direction D2 by plug isolation layers 117.

A contact spacer 116 may be disposed between the storage node contacts 115 and the plug isolation layer 117. The contact spacer 116 may be a portion where the surface of each storage node contact 115 is converted by a predetermined thickness through an oxidation process. From the perspective of a top view, referring to FIG. 1A, the contact spacer 116 may have different thicknesses at the central portion and at both ends. The thickness of the contact spacer 116 in the central portion may be thinner than the thickness of the contact spacer 116 at both ends.

Each of the contact spacer 116 and the plug isolation layer 117 may include a dielectric material. For example, the contact spacer 116 may include silicon oxide. For example, the plug isolation layer 117 may include silicon nitride, but the embodiments of the present disclosure are not limited thereto.

A memory element ME may be formed over the storage node contacts 115. The memory element ME may include a capacitor including a storage node. The storage node may include a pillar type. Although not illustrated, a dielectric layer and a plate node may be further formed over the storage node. The storage node may have a cylinder type other than a pillar type.

As described above, according to the present embodiment of the present disclosure, the peak of the storage node contact 115 may be removed and the interference between the storage node contacts 115 may be alleviated or minimized by applying the contact spacer 116 in which the surface of the storage node contact 115 is converted with an oxide. Accordingly, the parasitic capacitance of the cell transistor may be reduced and the sensing margin may be improved.

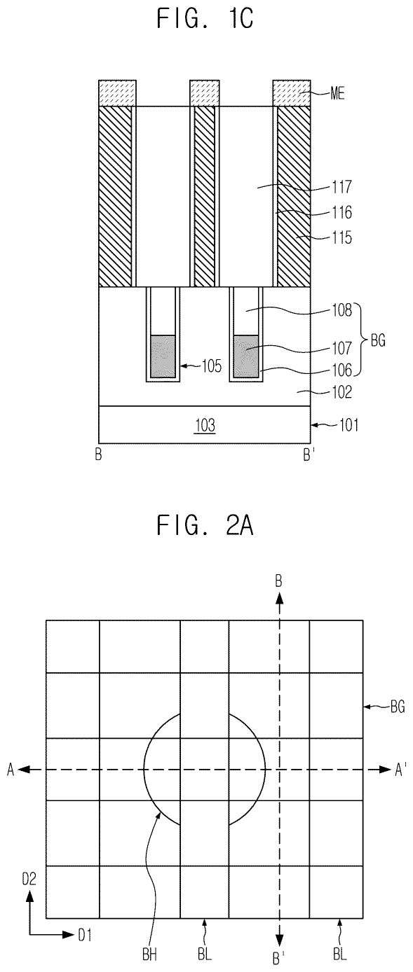

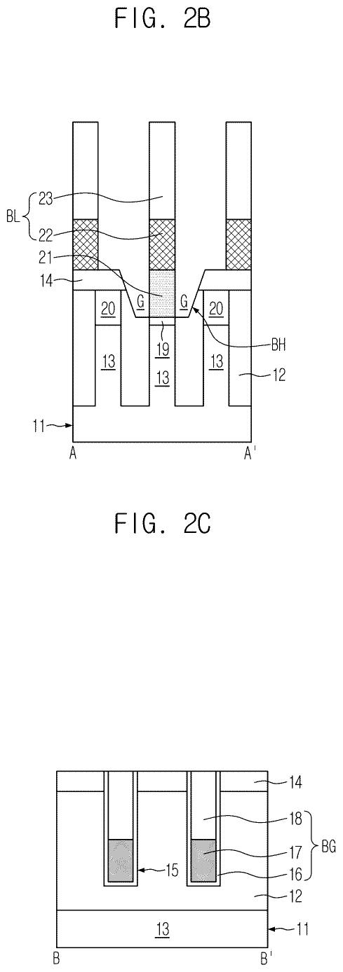

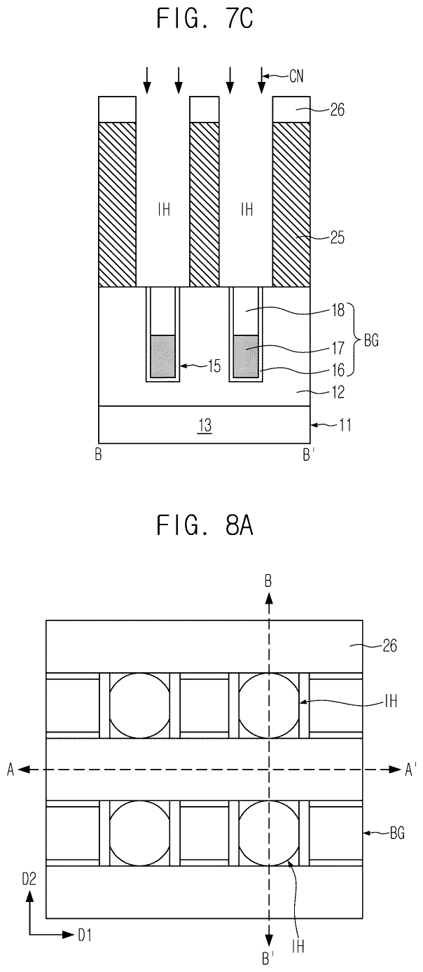

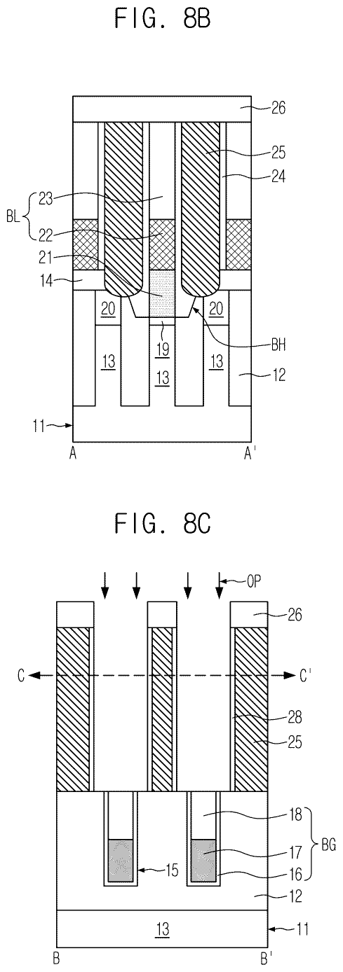

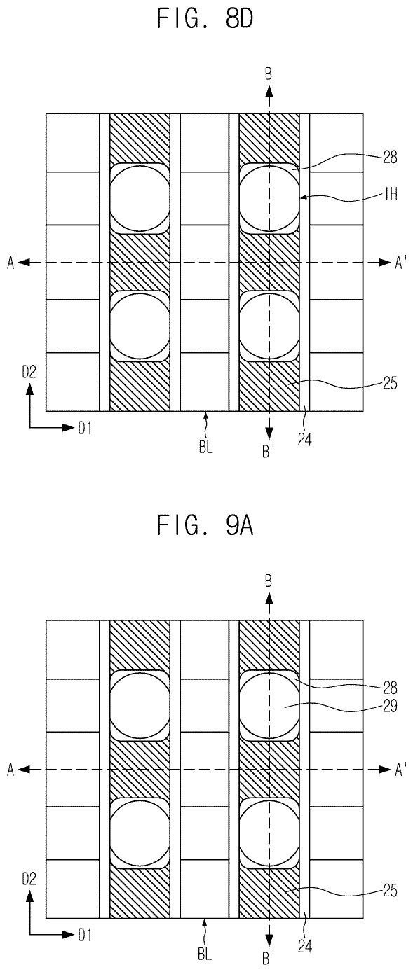

FIG. 2A to FIG. 10C illustrate a method for fabricating a semiconductor device in accordance with an embodiment of the present disclosure. FIGS. 2A, 3A, 4A, 5A, 6A, 7A, 8A, 9A and 10A are plan views. FIGS. 2B, 3B, 4B, 5B, 6B, 7B, 8B, 9B and 10B are cross-sectional views taken along a line A-A′ of FIGS. 2A, 3A, 4A, 5A, 6A, 7A, 8A, 9A and 10A. FIGS. 2C, 3C, 4C, 5C, 6C, 7C, 8C, 9C and 10C are cross-sectional views taken along a line B-B′ of FIGS. 2A, 3A, 4A, 5A, 6A, 7A, 8A, 9A and 10A. FIG. 8D is a plan view taken along a line C-C′ of FIG. 8C.

Referring to FIGS. 2A to 2C, an isolation layer 12 may be formed over a substrate 11. An active region 13 may be defined by the isolation layer 12. Each active region 13 may have an elongated bar shape. A plurality of active regions 13 may be disposed to be spaced apart from each other by a predetermined interval.

The isolation layer 12 may be formed by a Shallow Trench Isolation (STI) process. The STI process may be performed as follows. The substrate 11 may be etched to form an isolation trench (whose reference numeral is omitted). The isolation trench may be filled with a dielectric material, and thus the isolation layer 12 may be formed. The isolation layer 12 may include silicon oxide, silicon nitride, or a combination thereof. Chemical Vapor Deposition (CVD) or another deposition process may be used to fill the isolation trench with the dielectric material. A planarization process such as Chemical Mechanical Polishing (CMP) may additionally be used.

Subsequently, a buried gate structure BG may be formed in the substrate 11. The buried gate structure BG may have a line shape extending in the first direction D1. The buried gate structure BG may be referred to as a ‘buried word line structure’. The buried gate structure BG may include a gate trench 15, a gate dielectric layer 16 covering the bottom surface and sidewall of the gate trench 15, a gate electrode 17 partially filling the gate trench 15 over the gate dielectric layer 16, and a gate capping layer 18 formed over the gate electrode 17.

A method for forming the buried gate structure BG may be performed as follows.

First, the gate trench 15 may be formed in the substrate 11. The gate trench 15 may have a line shape crossing the active region 13 and the isolation layer 12. The gate trench 15 may be formed by forming a mask pattern (not shown) over the substrate 11 and performing an etching process using the mask pattern as an etching mask. In order to form the gate trench 15, a hard mask layer 14 may be used as an etching barrier. The hard mask layer 14 may include TEOS, but the embodiments of the present disclosure are not limited thereto. The gate trench 15 may be formed to be shallower than the isolation trench. The bottom surface of the gate trench 15 may be disposed at a higher level than the bottom surface of the isolation layer 12. The depth of the gate trench 15 may be sufficiently deep to increase the average cross-sectional area of the gate electrode 17. Accordingly, the resistance of the gate electrode 17 may be reduced. According to another embodiment of the present disclosure, the bottom edges of the gate trench 15 may have a curvature. By forming the bottom edges of the gate trench 15 to have a curvature, the unevenness at the bottom portion of the gate trench 15 may be minimized, and thus, the filling of the gate electrode 17 may be easily performed.

According to another embodiment of the present disclosure, after the formation of the gate trench 15, a fin region may be formed. The fin region may be formed by recessing a portion of the isolation layer 12.

Subsequently, the gate dielectric layer 16 may be formed on the bottom surface and sidewalls of the gate trench 15. Before the gate dielectric layer 16 is formed, etching damage on the surface of the gate trench 15 may be cured. For example, a sacrificial oxide may be formed by a thermal oxidation process, and then the sacrificial oxide may be removed.

The gate dielectric layer 16 may be formed by a thermal oxidation process. For example, the bottom and sidewalls of the gate trench 15 may be oxidized to form the gate dielectric layer 16.

According to another embodiment of the present disclosure, the gate dielectric layer 16 may be formed by a deposition process, such as a Chemical Vapor Deposition (CVD) process or an Atomic Layer Deposition (ALD) process. The gate dielectric layer 16 may include a high-k material, an oxide, a nitride, an oxide nitride, or a combination thereof. The high-k material may include a hafnium-containing material. The hafnium-containing material may include hafnium oxide, hafnium silicon oxide, hafnium silicon oxynitride, or a combination thereof. According to another embodiment of the present disclosure, the high-k material may include lanthanum oxide, lanthanum aluminum oxide, zirconium oxide, zirconium silicon oxide, zirconium silicon oxynitride, aluminum oxide, and a combination thereof. Other known high-k materials may be selectively used as the high-k material.

According to another embodiment of the present disclosure, the gate dielectric layer 16 may be formed by depositing a liner polysilicon layer and then radically oxidizing the liner polysilicon layer.

According to another embodiment of the present disclosure, the gate dielectric layer 16 may be formed by forming a liner silicon nitride layer and then radically oxidizing the liner silicon nitride layer.

Subsequently, the gate electrode 17 may be formed over the gate dielectric layer 16. To form the gate electrode 17, a conductive layer (not shown) may be formed to fill the gate trench 15, and then a recessing process may be performed. As for the recessing process, an etch-back process may be performed, or a Chemical Mechanical Polishing (CMP) process and an etch-back process may be performed sequentially. The gate electrode 17 may have a recessed shape that partially fills the gate trench 15. The upper surface of the gate electrode 17 may be disposed at a lower level than the upper surface of the substrate 11. The gate electrode 17 may include a metal, a metal nitride, or a combination thereof. For example, the gate electrode 17 may be formed of titanium nitride (TiN), tungsten (W), or titanium nitride/tungsten (TiN/W). Titanium nitride/tungsten (TiN/W) may have a structure that is formed by conformally forming titanium nitride and then partially filling the gate trench 15 by using tungsten. Titanium nitride may be used alone as the gate electrode 17, which may be referred to as a gate electrode 17 having a ‘TiN Only’ structure. According to another embodiment of the present disclosure, the gate electrode 17 may include a stacked structure of a metal and polysilicon.

Subsequently, the gate capping layer 18 may be formed over the gate electrode 17. The gate capping layer 18 may include a dielectric material. The remaining portion of the gate trench 15 may be filled with the gate capping layer 18 over the gate electrode 17. The gate capping layer 18 may include silicon oxide. According to another embodiment of the present disclosure, the gate capping layer 18 may have a NON (Nitride-Oxide-Nitride) structure. The upper surface of the gate capping layer 18 may be disposed at the same level as the upper surface of the hard mask layer 14. To this end, a Chemical Mechanical Polishing (CMP) process may be performed by using the upper surface of the hard mask layer 14 as an etch stop target when the gate capping layer 18 is formed.

After the formation of the buried gate structure as described above, a first junction region 19 and a second junction region 20 may be formed. The first source/drain region 19 and the second junction region 20 may be formed by a doping process such as an implantation process. The first junction region 19 and the second junction region 20 may have the same depth. According to another embodiment of the present disclosure, the first junction region 19 may be deeper than the second junction region 20. The first junction region 19 may be a region to which a bit line contact is to be coupled. The second junction region 20 may be a region to which a storage contact is to be coupled.

A cell transistor of a memory cell may be formed by the gate electrode 17, the first junction region 19, and the second junction region 20.

Subsequently, a bit line structure BL coupled to the first junction region 19 may be formed. The bit line structure BL may include a stacked structure of a bit line 22 and a bit line hard mask 23. The bit line structure BL may have a line shape extending in the second direction D2 which is perpendicular to the first direction D1.

A method of forming the bit line structure BL may be performed as follows.

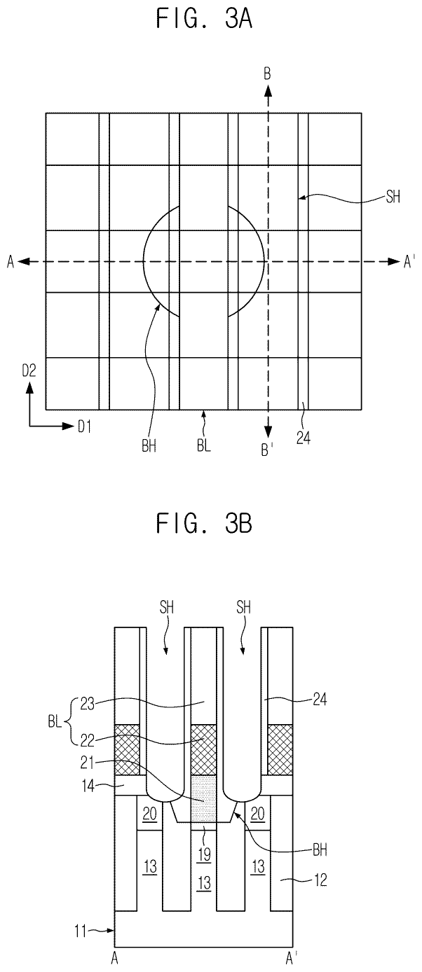

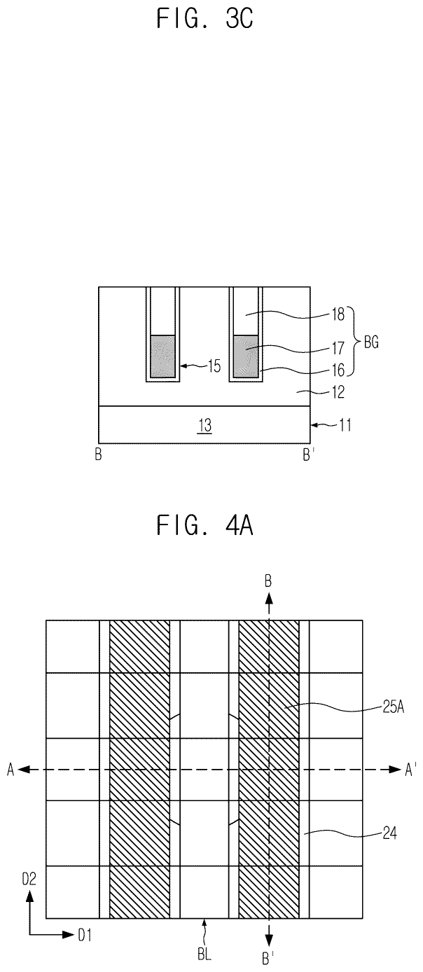

First, the hard mask layer 14 may be etched to form a bit line contact hole BH. Referring to FIG. 3A, the bit line contact hole BH may have a circular shape or an elliptical shape. A portion of the substrate 11 may be exposed by the bit line contact hole BH. The bit line contact hole BH may have a diameter that is controlled to a predetermined line width. The bit line contact hole BH may expose a portion of the active region 13. For example, the bit line contact hole BH may expose the first junction region 19. The bit line contact hole BH may have a diameter which is larger than the width of the short axis of the active region 13. Therefore, in the etching process for forming the bit line contact hole BH, the first junction region 19, the isolation layer 12, and a portion of the gate capping layer 18 may be etched. The gate capping layer 18, the first junction region 19, and the isolation layer 12 below the bit line contact hole BH may be recessed to a predetermined depth. As a result, the bottom portion of the bit line contact hole BH may extend into the inside of the substrate 11. As the bit line contact hole BH extends, the first junction region 19 may be recessed, and the upper surface of the first junction region 19 may be lower than the upper surface of the second junction region 20.

Subsequently, a preliminary plug (not shown) for gap-filling the bit line contact hole BH may be formed. The preliminary plug may be formed by a Selective Epitaxial Growth (SEG) process. For example, the preliminary plug may include SEG SiP, but the embodiments of the present disclosure are not limited to. In this way, the preliminary plug may be formed without voids by the Selective Epitaxial Growth (SEG) process. According to another embodiment of the present disclosure, the preliminary plug may be formed by a polysilicon deposition process and a Chemical Mechanical Polishing (CMP) process. The preliminary plug may fill the bit line contact hole BH. The upper surface of the preliminary plug may be disposed at the same level as the upper surface of the hard mask layer 14.

Subsequently, a conductive layer (not shown) and a hard mask material layer (not shown) may be stacked over a hard mask layer 14 including a preliminary plug. The conductive layer and the hard mask material layer may be sequentially stacked over the preliminary plug and the hard mask layer 14. The conductive layer may include a metal-containing material. The conductive layer may include a metal, a metal nitride, a metal silicide, or a combination thereof. According to the embodiment of the present disclosure, the conductive layer may include tungsten (W). According to another embodiment of the present disclosure, the conductive layer may include a stack of titanium nitride and tungsten (TiN/W). Here, the titanium nitride may serve as a barrier. The hard mask material layer may be formed of a dielectric material having an etching selectivity with respect to the conductive layer and the preliminary plug. The hard mask material layer may include silicon oxide or silicon nitride.

Subsequently, a bit line mask layer (not shown) may be formed over the hard mask material layer. The bit line mask layer may be formed of a material having an etching selectivity with respect to the conductive layer and the hard mask material layer. The bit line mask layer may include a photosensitive layer pattern. The bit line mask layer may be formed by a patterning method, such as SPT or DPT.

Subsequently, the hard mask material layer, the conductive layer, and the preliminary plug may be etched sequentially. As a result, the bit line contact 21, the bit line 22, and the bit line hard mask 23 may be formed. The stacked structure of the bit line 22 and the bit line hard mask 23 may be referred to as a ‘bit line structure BL’.

The line width of the bit line structure BL may be thinner than the diameter of the bit line contact hole BH. Therefore, a gap G may be formed in the peripheral area of the bit line contact 21. The gap G may not be of a surrounding shape that surrounds the bit line contact 21, but may be independently formed on both sidewalls of the bit line contact 21. As a result, one bit line contact 21 and a pair of gaps G may be disposed in the bit line contact hole BH, and the pair of gaps G may be separated by the bit line contact 21. The bottom surface of the gap G may be disposed at the same level as the recessed upper surface of the first junction region 19. According to another embodiment of the present disclosure, the bottom surface of the gap G may extend into the inside of the isolation layer 12. The bottom surface of the gap G may be disposed at a lower level than the recessed upper surface of the first junction region 19.

Referring to FIGS. 3A to 3C, a bit line spacer 24 may be formed on both sidewalls of the bit line structure BL.

The bit line spacer 24 may extend in the second direction D2 along the bit line structure BL. The bit line spacer 24 may extend from the bit line structure BL to the bit line contact 21. The bit line spacer 24 may fill the gap G between the bit line contact hole BH and the bit line contact 21.

The bit line spacer 24 may include a single-layer structure or a multi-layer structure. The bit line spacer 24 may include a dielectric material. For example, the bit line spacer 24 may include a combination of at least one among silicon oxide, silicon nitride, and a low-k material. Here, the low-k material may refer to a material having a higher dielectric constant than silicon oxide and a lower dielectric constant than silicon nitride.

Subsequently, the hard mask layer 14 exposed between the bit line spacers 24 may be etched to form a storage node contact hole SH that exposes the second junction region 20.

The storage node contact hole SH may extend into the inside of the substrate 11. The bottom surface of the storage node contact hole SH may be disposed at a lower level than the upper surface of the bit line contact 21. The bottom surface of the storage node contact hole SH may be disposed at a higher level than the bottom surface of the bit line contact 21.

The storage node contact hole SH may have a line shape extending in the second direction D2.

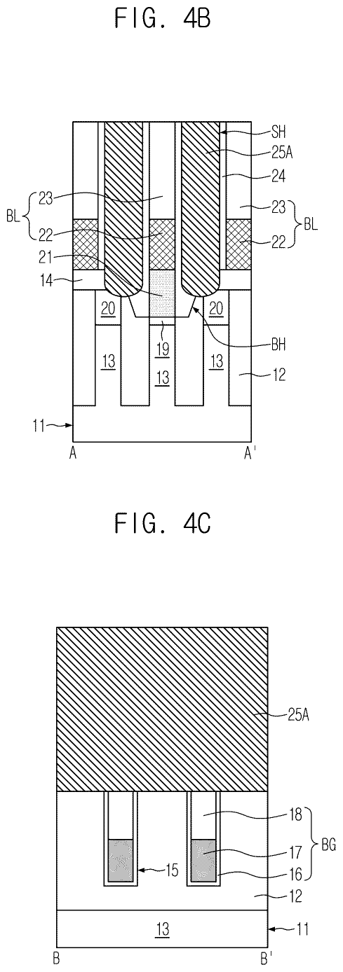

Referring to FIGS. 4A to 4C, a plug material layer 29A that fills the storage node contact hole SH may be formed. The plug material layer 29A may be formed to gap-fill all line-type storage node contact holes SH that are exposed by the bit line structure BL and the bit line spacer 24. The plug material layer 25A may include a conductive material. For example, the plug material layer 25A may include polysilicon.

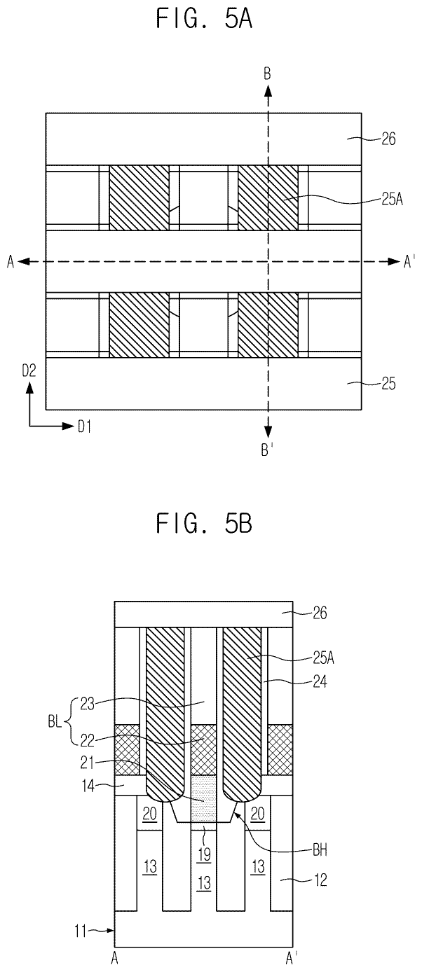

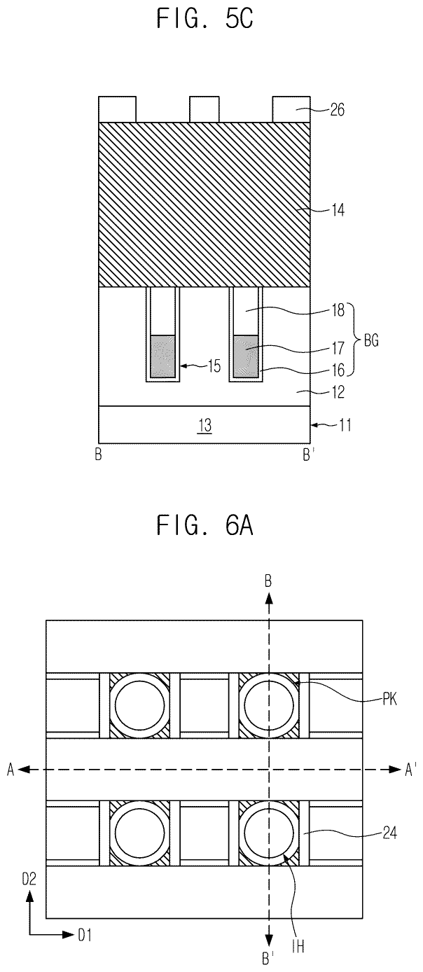

Referring to FIGS. 5A to 5C, a mask pattern 26 may be formed over the plug material layer 25A and the bit line structure BL.

The mask pattern 26 may be of a line shape extending in the first direction D1. The mask pattern 26 may be spaced apart in the second direction D2. The mask pattern 26 may include a dielectric material having an etching selectivity with respect to the plug material layer 25A and the bit line hard mask 23.

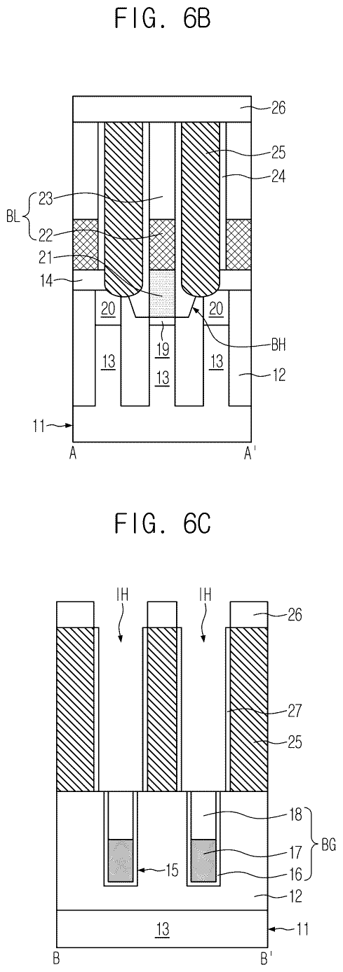

Referring to FIGS. 6A to 6C, the plug material layer 25A (see FIG. 5B) exposed by the mask pattern 26 may be etched to form storage node contacts 25. A plug isolation portion IH may be formed between the storage node contacts 25. Each of the storage node contacts 25 may be electrically connected to the second junction region 20. The plug isolation portion IH may isolate the storage node contacts 25 in the second direction D2. The storage node contacts 25 may be an island shape that is separated in the first direction D1 by the bit line structure BL and separated in the second direction D2 by the plug isolation portion IH.

While the etching process is performed to form the storage node contacts 25, a natural oxide layer 27 may be formed on the sidewall.

Each of the storage node contacts 25 may have a peak PK that is formed as the corner portion where the mask pattern 26 and the bit line spacer 24 intersect with each other is not completely etched. To be specific, since the surface exposed to an etchant is blocked at the material boundary, the exposed surface may be small. Therefore, the peak may be formed due to the insufficient etching as it approaches the bit line spacer 24.

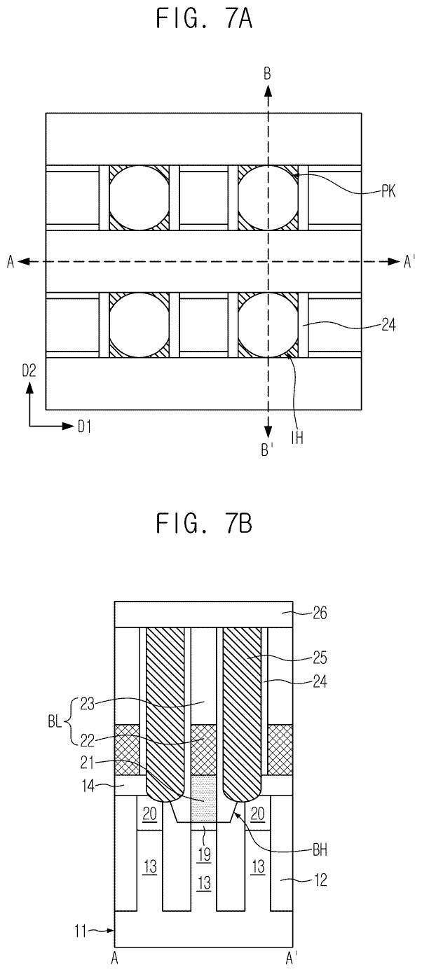

Referring to FIGS. 7A to 7C, the natural oxide layer 27 (see FIG. 6B) may be removed. The natural oxide layer 27 may be removed through a cleaning process CN. The cleaning process CN may be performed by using a wet chemical. For example, HF or BOE may be used as the wet chemical. However, the embodiments of the present disclosure are not limited thereto, and all wet chemicals capable of removing an oxide layer may be applied.

Therefore, the sidewall of each of the storage node contacts 25 may be exposed.

The subsequent oxidation process may be performed smoothly by removing the natural oxide layer 27 through the cleaning process and exposing the sidewall of each of the storage node contacts 25. As a comparative example, when the subsequent process is performed without performing the cleaning process, there may be a problem in that the natural oxide layer 27 covers the storage node contacts 25 to prevent additional oxidation from occurring, or even though an additional oxidation occurs, the thickness may be so thin that it is difficult to be applied as a spacer.

Referring to FIGS. 8A to 8D, a contact spacer 28 may be formed on the sidewall of each storage node contact 25.

The contact spacer 28 may refer to a region where the surface of each storage node contact 25 is oxidized to a portion of the thickness. The contact spacer 28 may be formed through an oxidation process OP. For example, the oxidation process may include an oxygen treatment process using O₂ plasma.

According to another embodiment of the present disclosure, the oxidation process may include a thermal oxidation process or a wet oxidation process using H₂O.

As a portion of the surface of each storage node contact 25 is substituted by the contact spacer 28 during the oxidation process OP, the peak PK (see FIG. 6A) of each storage node contact 25 may be alleviated or minimized. To be specific, the oxidation process OP may be performed on the exposed surface that may react with oxygen, and more oxidation may occur in the area with more exposed surface. Since the portion where the peak PK is disposed is less etched, it may have a greater surface exposed to the outside. Therefore, more oxidation may occur there.

Therefore, referring to FIG. 8D, the thickness of the contact spacer 28 may become thicker as it goes toward the corner where the mask pattern 26 and the bit line spacer 24 intersect with each other. The thickness of the contact spacer 28 may become thicker as it goes from the central portion toward both ends. In the contact spacer 28, the thickness at the central portion may be thinner than the thickness at the end of one side.

In particular, according to the embodiment of the present disclosure, the process difficulty and process costs may be reduced by applying an oxygen treatment process using O₂ plasma as the oxidation process.

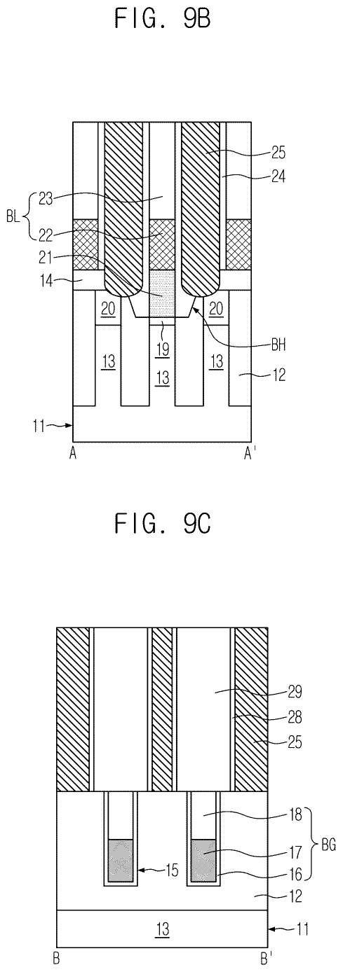

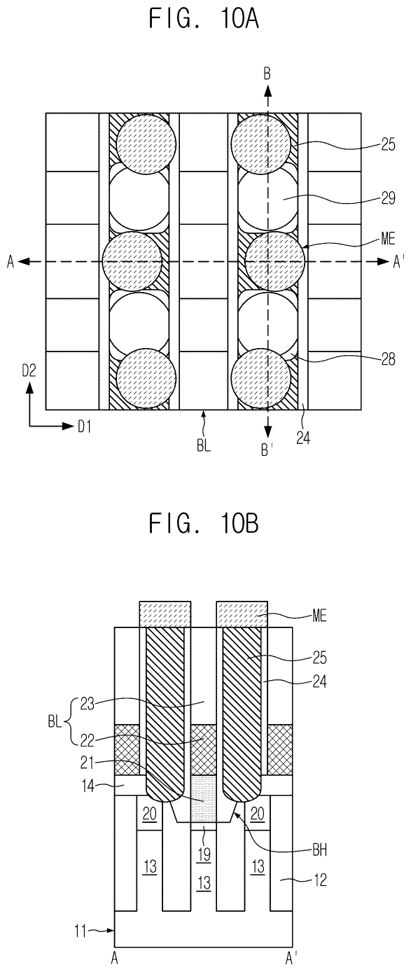

Referring to FIGS. 9A to 9C, a plug isolation layer 29 filling the plug isolation portion IH may be formed.

The plug isolation layer 29 may be formed through a process of gap-filling the plug isolation portion IH with a dielectric material. The plug isolation layer 29 may be formed through two or more gap-fill processes. To be specific, the plug isolation layer 29 may be formed by repeatedly performing the processes of gap-filling the plug isolation portion IH with a dielectric material and etching a portion of the dielectric material in the upper portion of the plug isolation portion IH.

According to another embodiment of the present disclosure, the plug isolation layer 29 may be formed through a gap-fill process that is performed once.

The plug isolation layer 29 may include a dielectric material. For example, the plug isolation layer 29 may include silicon nitride. According to another embodiment of the present disclosure, the plug isolation layer 29 may include silicon oxide.

The contact spacer 28 and the plug isolation layer 29 may serve to isolate the storage node contacts 25.

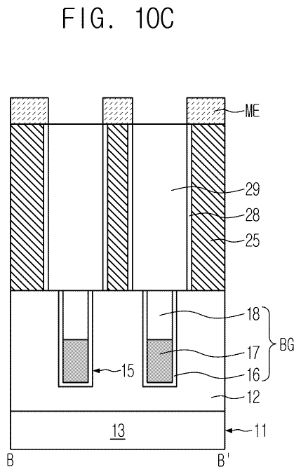

Referring to FIGS. 10A to 10C, a memory element ME may be formed over each storage node contact 25.

The memory element ME may include a capacitor including a storage node. The storage node may include a pillar type. Although not illustrated, a dielectric layer and a plate node may be further formed over the storage node. The storage node may have a cylindrical shape other than a pillar shape.

According to another embodiment of the present disclosure, before the memory element ME is formed, an inter-layer dielectric layer including a landing pad may be further included over each storage node contact 25.

According to the embodiment of the present disclosure, the interference between the neighboring storage nodes may be improved.

According to the embodiment of the present disclosure, the parasitic capacitance of cell transistors may be reduced, and the sensing margin may be improved.

According to the embodiment of the present disclosure, the reliability of a semiconductor device may be improved.

While the present invention has been described with respect to the specific embodiments, it will be apparent to those skilled in the art that various changes and modifications may be made without departing from the spirit and scope of the embodiments as defined in the following claims. Furthermore, the embodiments may be combined to form additional embodiments.

What is claimed is:

1. A semiconductor device comprising:
a semiconductor substrate;
a plurality of bit line structures disposed over the semiconductor substrate;
island-shaped storage node contacts that are spaced apart from each other between neighboring bit line structures of the plurality of bit line structures;
a plurality of plug isolation layers disposed between the island-shaped storage node contacts; and
contact spacers disposed between each of the storage node contacts and each of the plurality of plug isolation layers, each contact spacer having different thicknesses at a central portion and at both ends.

2. The semiconductor device of claim 1, wherein:
the plurality of bit line structures are spaced apart from each other in a first direction; and
each of the plurality of bit line structures has a line shape extending in a second direction orthogonal to the first direction.

3. The semiconductor device of claim 1, wherein the island-shaped storage node contacts and the plurality of plug isolation layers are alternately disposed in the second direction.

4. The semiconductor device of claim 1, wherein each contact spacer has a thickness at the central portion thinner than a thickness at both ends.

5. The semiconductor device of claim 1, wherein each contact spacer includes an oxide.

6. The semiconductor device of claim 5, wherein the oxide is obtained by oxidation of a surface of the island-shaped storage node contacts.

7. The semiconductor device of claim 1, wherein the contact spacers include silicon oxide.

8. The semiconductor device of claim 1, wherein the plurality of plug isolation layers include silicon nitride.

9. The semiconductor device of claim 1, further comprising:
bit line spacers disposed between the plurality of bit line structures and the island-shaped storage node contacts.

10. The semiconductor device of claim 9, wherein the bit line spacers extend along both sidewalls of each bit line structure.

11. The semiconductor device of claim 1, further comprising:
a buried gate structure disposed within the semiconductor substrate; and
first and second junction regions that are spaced apart from each other by the buried gate structure.

12. The semiconductor device of claim 11, wherein each bit line structure is coupled to the first junction region, and each island-shaped storage node contact is coupled to the second junction region.

13. The semiconductor device of claim 1, further comprising:
a bit line contact suitable for coupling between the semiconductor substrate and the bit line structure.

14. The semiconductor device of claim 1, further comprising:
memory elements that are disposed over the island-shaped storage node contacts and coupled to the island-shaped storage node contacts.
